(19) United States
(12) Patent Application Publication
(10) Pub. No.: US 2008/0187660 A1
(43) Pub. Date: Aug. 7, 2008

(54) Method and device for the localized application of parting means

(76) Inventor: Stefan Hein, Blankenbach (DE)

Correspondence Address: FULBRIGHT & JAWORSKI, LLP, 666 FIFTH AVE, NEW YORK, NY, 10103-3198, US

(21) Appl. No.: 12/074,005

(22) Filed: Feb. 29, 2008

Related U.S. Application Data
(62) Division of application No. 10/880,987, filed on Jun. 30, 2004.

(30) Foreign Application Priority Data
Jul. 4, 2003 (DE) 103 30 401.0

(51) Int. Cl. C23C 16/44

(52) U.S. Cl. 427/248.1

(57) ABSTRACT

A method for locally applying onto a moving substrate in a vacuum chamber a parting means preventing coating using a heatable vaporizer.

The invention relates to a method for the localized application by means of a vaporizer of a parting means preventing coating, onto movable substrates in a vacuum chamber, which comprises at least one metal vaporizer, the parting means being vaporized in a first chamber by heating and transferred in the vapor state via at least one setting valve into a second chamber provided with at least one nozzle directed onto the particular substrate.

The aim is here the generation of strips of the parting means, in the following inter alia also referred to as “oil tracings”, on the movable or moving substrates. Such “oil tracings” are expected to have a specified constant distribution pattern with respect to the substrate margins, constant thickness and width. Additional requirements will be discussed later in further detail.

DE 21 12 405 A1 addresses the problem of suppressing the regulation hunting of the vapor quantity during the vapor deposition on films. The oil vaporizer comprises only a single cylindrical chamber, which, in the lower region, is filled with an oil-like liquid having a large surface and which is encompassed by its own cylindrical heating winding and further is provided above the oil level with radial nozzles, through which the oil vapor for the formation of oil strips is directed against the running film. In the liquid region are further provided a temperature sensor and a horizontal U-form heating and cooling coil for a coarse adjustment of the temperature of the liquid through compressed air, the quantity and temperature of which is regulated through solenoid valves. For regulating the level a further regulation system with a float valve is provided for the regulation according to the principle of communicating tubes. The width of one of the oil strips on the film is monitored by a diffuse, namely conical, light beam between a light source and a photoelectric transducer, whose output signal acts onto the valves of the compressed air cooling system. The diffuse light beam acquires within its cone of light also subregions of the metal layers, whereby the accuracy of the proportional regulation is impaired and a dislocation of the precise position of the oil strip within the cone of light cannot be acquired. While the patent states that the regulation is to take place with low inertia, however. the regulation range should be kept small. After the passage of the film, oil vapor necessarily still flows through the nozzles contaminating the roller, over which the film is guided, and the vacuum chamber in which the entire vaporization system is disposed. The regulation systems are in addition structured such that they are extremely complex.

DE 39 22 187 Al discloses vaporizing materials which prevent local coating, and are also referred to as parting means, in a heated vaporization tube and to conduct them directly from the vapor space above the liquid—as a rule an oil—into nozzles, each of which directs a vapor jet onto a moving band in order to generate during the vapor condensation of metals longitudinal strips which are free of metal. Disclosed is also a television camera for observing the metallization process, but not the application of the oil.

From DE 41 00 643 C1 it is furthermore known to generate additional metal-free transverse strips through a roller rotating at the rate of the band, into which also vapor is conducted unhindered from the vapor space of the oil vaporizer. The oil temperature in the vaporizer can be monitored by a temperature sensor.

From DE 42 31 644 A1 it is known to affect the distribution pattern of the metal-free regions thereby that above the vapor space and in front of the slot nozzles a movable aperture is disposed with cutouts and tongues having different lengths. However, the patent expressly specifies that one slot nozzle must always be left free.

From DE 43 09 717 A1 it is also known to configure slot nozzles directly above the vapor space of the heated vaporizer and to adjust the layer thickness of the oil layer by controlling the heating power of the oil vaporizer.

EP 0 966 006 A2 discloses producing film capacitors thereby that during each rotation of a rotating highly polished cylinder successively is applied a cured isolating resin layer of reactive monomeric vapors, parting layers patterned in the form of strips, and metal layers, also patterned in the form of strips complementary to them, from the group of aluminum, copper, zinc, nickel, their alloys and-oxides. A shell of layers is generated by a multiplicity of up to 1800 rotations in the form of spirals until the desired electrostatic capacitance of the capacitor has been attained. The multilayered shell is subsequently cut open transversely to the direction of rotation, lifted from the cylinder, pressed flat under the action of heat, further separated and provided with electrodes. Measurements of the resin thickness with laser light are also specified. Measurements of the layer width by measuring reflections and color contrasts by means of a camera are also specified. While a vapor distributor provided with nozzles for the material of the parting layers, namely vapors from the group of oils of esters, glycols, tetrafluorocarbons and hydrocarbons, is specified, means and measures for the control of the vapor quantity and of the layer thickness and for the interruption of the vapor streams during a stand-down of the installation are not. It is even expressly stated that it is not required to determine the thicknesses of all individual layers with each rotation of the cylinder, and that it is sufficient to reach a certain electrostatic capacitance at the end. It is for example sufficient to carry out a determination of a layer thickness at a measuring point (“check point”) after 15 initial rotations of the cylinder. For aluminum a layer thickness of 30 nm (300 A) is specified, but regarding the parting means it is only stated that excess parting means must be removed again through a plasma discharge. But, especially in the case of halogen compounds as parting means, thereby deleterious compounds are formed which are damaging to the pump oil. For the cured resin layer a thickness of not more than 1 μm is specified. The fundamental aim in this patent is only the measurement and control or regulation of the thickness of the insulating layer or resin layer and of the metal layer and the width of the metal and of the parting layers, since these parameters are decisive for the capacitance of the capacitor. A repetition at certain measuring points (“check points”) after further rotations is optionally provided. This document does not at all address the problem of continuous outflows of oils or parting means during pauses in the operation, as well as avoiding the displacements of the oil tracings due to fluctuations of temperature and length of the oil vaporizer.

DE 198 48 177 A1 discloses providing an elongated nozzle body with several nozzle openings, which, for the purpose of generating parting means strips on films, is connected to a parting means vaporizer of minimum size. The nozzle body and the parting means vaporizer are disposed spaced apart from one another and can be connected via a shutoff valve and not a regulation valve. The vapor quantity regulation is said to take place with fully open shutoff valve via the regulation of the temperature of the heating power of the parting means vaporizer. Due to the mass, a temperature-dependent regulation of the vapor quantity is still inertial even if the parting means vaporizer and its filling volume are kept very small. While condensation of vapor in the nozzle body and the continued afterflow of vapor onto the film and into the installation can be prevented by closing the valve and by heating the nozzle body, however, the change of the vapor quantity through temperature regulation of the parting means vaporizer also leads to a change of the temperature of the nozzle body and therewith to a change of its length and, in addition, to changes of the thermal and the local condensation conditions on the film.

On physical grounds, vaporization can only take place above the boiling point, otherwise the process is referred to as evaporation, which, however, only takes place in small quantities. But the boiling point is a function of the pressure. The nozzle body does have outlet openings of limited cross section, which, in addition, are also covered gap-free by the curved film to be vapor deposited. Thus if the vapor quantity per-unit time is increased by temperature increases, the counter pressure increases and therewith the boiling temperature and logically also the vapor temperature and the temperature of the nozzle body, which, in turn, has a negative effect on its length and the position of the oil tracings on the film. Added to this is that the heat of vaporization on the film surface is again released as heat of condensation, which, due to the contact of the film with the nozzle body, which is heated in any event, is again at least partially transferred to it, and which aggravates the conditions further.

The listed parting means and metals and their alloys and compounds can, in principle, also be applied to the subject matter of the invention.

The above solutions have the disadvantages that, due to their unavoidable thermal inertia, the vaporizers emit oil vapor even during the stand-down of the installation, for example during a band exchange or an operational breakdown, whereby the installation becomes considerably contaminated. Contaminations through oil are difficult to remove, especially since they form a grease with other contaminants.

A further significant problem is not addressed at all by prior art: the thermally conditioned change in length of the vaporizer during heating and cooling. If the oil emission is to be decreased, it is essential to cease heating the vaporizer and to heat it again when the installation is taken into operation again. This leads to time losses and, in any case, to a decrease of the oil emission. But the constant distribution of the nozzles, and therewith of the “oil tracings” along the bands, is essential for the flawless quality of the end products.

Different solutions for interrupting the vapor'stream from a vaporizer to a nozzle row are disclosed in EP 1 035 553 A1 and EP 0 938 971 A2. For one, there are shutoff valves between vaporizers, which are disposed outside of the vacuum chamber, and nozzle bodies in the interior of the vacuum chamber.

The closest prior art from EP 1 035 553 A1 is the example according to FIG. 7. The oil vaporizer is a heatable block with two parallel channels, which are connected with one another through a slot for the vapor flow, the block being heated to a temperature above the boiling point of the oil. The lower channel is filled with a supply of the oil, and the upper channel is provided with a row of nozzles for the vapor outlet in the direction toward the band in order to generate in this way oil tracings on the band. Shutoff valves or adjusting valves between the two channels are not disclosed; a single external shutoff valve is only provided between a supply container, which is also externally disposed, for the cold oil and the lower internal supply channel for the liquid oil. But, again, this does not prevent the oil vapors from emerging through the row of nozzles into the vacuum chamber of the installation and condensing here even after the liquid valve has been switched off. The problem of the change in length of the oil vaporizer with a change of the temperature is here also not addressed. But significant is the statement, that while hereby a very simple configuration can be attained, it is, however, subject to the effect of a pressure change of the parting means (oil), such that the emitted quantity of oil has a tendency to become unstable.

The invention therefore addresses the problem of improving a method of the species described in the introduction, i.e. with a supply of liquid parting means in a two-chamber vaporizer with a vapor distribution chamber and nozzles within the vacuum chamber, to the effect that, in spite of keeping the vaporizer temperature constant, the quantities of vapor emerging from the nozzles can be specifically varied and are not dependent on random chance, and that the vapor emergence, if necessary, can be interrupted virtually immediately.

Solving the formulated problem in the method described in the introduction takes place according to the invention thereby that

a) the vaporizer temperature is kept constant as far as possible,

b) the vapor from the first chamber via the at least one setting valve is supplied under control into the second chamber and in the latter initially parallel to the first chamber to the at least one nozzle, and that

c) the setting valve is closed and kept closed in the event the band stands still or is absent.

The term “control” always includes also “regulation” through one or several closed regulation circuits.

This solution solves the formulated problem fully and completely. Stated differently, by keeping the vaporizer temperature constant, the length of the vaporizer, and therewith the distribution pattern of the nozzles and of the oil tracings generated by them, remain constant, and the quantities of vapor emerging from the nozzles can be controlled depending on the method. If necessary, the vapor emergence can also be interrupted practically immediately, such that a contamination of the vacuum chamber and its complexly distributed internal structures through oil condensation can practically be avoided and therewith also a frequent, difficult and labor-intensive cleaning of the installation.

Further advantageous embodiments of the method according to the invention are evident in the remaining method claims and the detailed description, in particular also the combinations and subcombinations, namely when

the liquid parting means contained in the first chamber is kept at constant temperature by at least one immersed electric heating body and if at least the wall of the second chamber, and therewith the at least one nozzle, is also kept at constant temperature by at least one further electric heating body, which is above the boiling temperature of the parting means,

the first chamber is disposed beneath and the second chamber in a higher position, and if the vaporous parting means is directed with a perpendicular direction component from below toward a band-form substrate,

the first chamber is disposed above and the second chamber in a lower position, and if the vaporous parting means is directed with a perpendicular direction component from above toward a plate-form substrate,

the wall temperature of the second chamber is adjusted to a higher value than the parting means temperature in the first chamber,

the heating power of the immersed heating body is adjusted as a function of the parting means temperature,

the heating power of the upper heating body for the at least one nozzle is adjusted as a function of the nozzle temperature,

the vapor quantity streaming from the first chamber over into the second chamber per unit time through the at least one proportional setting valve is adjusted as a function of the parting means requirement for the at least one nozzle,

the vapor quantity of parting means emerging from the at least one nozzle per unit time is adjusted as a function of the layer thickness and the width of the oil tracing(s) as well as the transporting rate of the band,

the layer thickness of the oil tracing(s) is adjusted proportionally to the metal quantity vaporized by the metal vaporizer per unit time,

the at least one oil tracing is passed through an observation field in which a visual check of the oil tracing(s) is carried out,

the operating parameters critical for the implementation of the distribution pattern and of the requisite thickness of the oil tracing(s) are supplied to a control system, in which they are converted into setting variables for the control and/or regulation of the vaporizer for the parting means, and/or when

the operating parameters critical for the implementation of the metal coating are also supplied to the control system, in which they are converted into setting variables for the control and/or regulation of the metal vaporizer.

The invention also relates to a device for the solution of the same problem. This device builds on the following prior art, namely on

a device for the localized application of parting means preventing a coating by means of a heatable vaporizer onto movable substrates in a vacuum chamber, which comprises at least one metal vaporizer, the parting means vaporizer comprising a first chamber with at least one heating body for the vaporization of the parting means, as well as a second chamber, which extends parallel to the first chamber, is connected with it and comprises at least one nozzle directed onto the particular band, and with at least one setting valve for blocking the supply of the parting means.

According to the invention, the solution of the formulated problem takes place in such a device thereby that

a) the at least one setting valve is a proportional valve, which is disposed between the first chamber and the second chamber,

b) the setting valve is in each instance disposed in one-channel of the parting means vaporizer, which channel connects the first chamber with the second chamber, and that

c) the setting valve is implemented such that the vapor stream of the parting means can be specifically adjusted in terms of quantity and is also completely interruptible.

Further advantageous embodiments of the device according to the invention are evident on the basis of the remaining device claims and the detailed description, in particular also based on combinations and subcombinations, namely when

the first chamber is disposed beneath and the second chamber in a higher position, and when the vaporous parting means can be directed with a perpendicular direction component from below against a band-form substrate,

the first chamber is disposed above and the second chamber in a lower position, and when the vaporous parting means is directed with a perpendicular direction component from above against a plate-form substrate,

in the first chamber for the liquid parting means at least one electric heating body is disposed and when at least the wall of the second chamber, and therewith the at least one nozzle, is in thermal contact with at least one further electric heating body,

the parting means vaporizer comprises a cuboidal chamber with a bottom and lateral flanges onto which is clamped an intermediate cover, which, in the direction of its longest extent, has a central recess open toward the top, at both sides of which grooves are disposed, in which the at least one further heating body is embedded, and when onto the intermediate cover a nozzle fitting bar is clamped, which, in the direction of its longest extent, has in the middle a recess open toward the bottom, the recesses communicating with one another forming the second chamber, from which extends the at least one nozzle,

the parting means vaporizer

a) comprises a first cuboidal chamber with a bottom and lateral flanges, onto which a first closure cover is clamped,

b) the second chamber includes a closure cover, which, in the direction of its longest extent, has a central recess open toward the top, at both sides of which grooves are disposed, in which the at least one further heating body is embedded, and when on the underside of the second closure cover a nozzle fitting bar is clamped on, which, in the direction of its longest extent, has a central recess open toward the top, the recesses communicating with one another forming the second chamber from which extends the at least one nozzle,

the nozzle fitting bar is implemented such that it can be exchanged against one such with other cross sections of the nozzles and/or a different distribution pattern of the nozzles,

in the first chamber of the parting means vaporizer below a structurally provided liquid level a temperature sensor for the temperature of the parting means is disposed,

the nozzle fitting bar has a recess with an end face on which the temperature sensor for the temperature of the nozzle fitting bar is in contact,

above the parting means vaporizer a deflector roller is disposed for the presetting of a running path of a band-form substrate and of the course of the at least one oil tracing generated by the nozzle(s) on the substrate, and when with the deflector roller are associated signal means for the determination of the substrate rate,

beneath the parting means vaporizer a transport path is disposed for plate-form substrates and of the course of at least one oil tracing on the substrate generated by the nozzle(s), and when associated with the transport path are signal means for the determination of the substrate rate,

associated with the running path of the substrate with the at least one oil tracing is an observation field, which can be scanned by optical means,

the measurement signals from sensors for the temperatures, the vapor quantity per unit time, the implementation of the distribution pattern and the thickness of the oil tracing(s) are sent to a control system, in which they are convertible into setting variables for the control and/or regulation of the vaporizer for the parting means (14),

to the control system a measurement and regulation configuration is connected for the control of the metal coating through the metal vaporizer,

with the control system an input keyboard is associated for setting commands and/or nominal values for the operating parameters, and/or when

with the control system a display screen is associated for measurement values, setting commands and/or nominal values for the operating parameters.

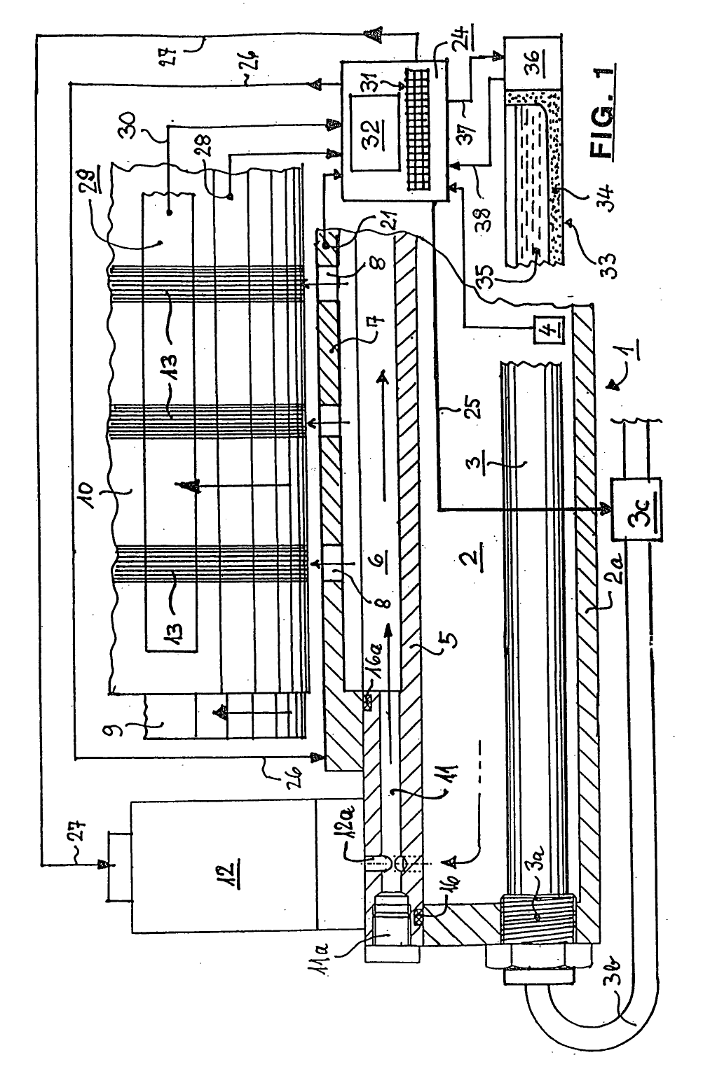

In the following, two embodiment examples of the subject matter of the invention and their operational functions and advantages will be explained in further detail in conjunction with FIGS. 1 to 4. Therein depict:

FIG. 1 an axial section through one end of a vaporizer for a parting means emergence perpendicularly upwardly, an axis-parallel side view of a cutout of an associated deflector roller and a band coated in the form of strips with the parting means, in connection with a highly simplified block circuit diagram for obtaining measured values and the output of control and regulation signals to the individual components acquired by measurement,

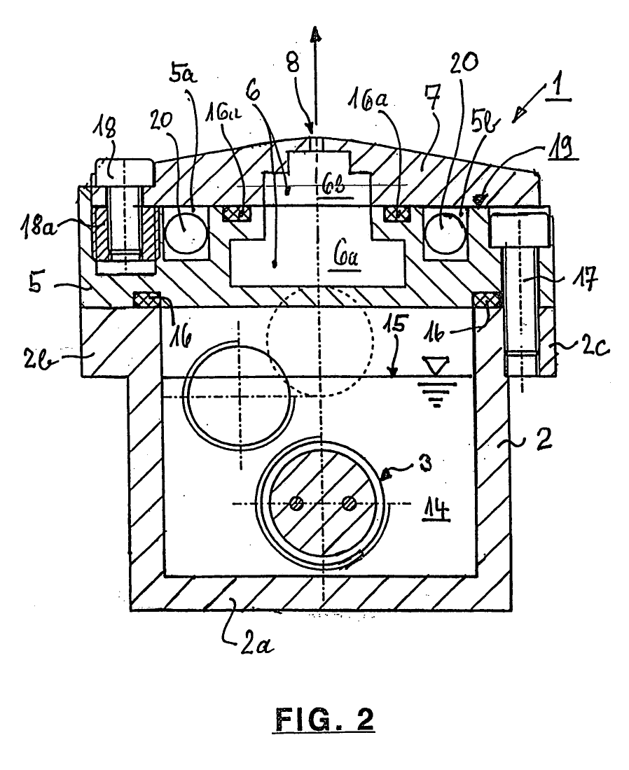

FIG. 2 a vertical cross section through the subject matter of FIG. 1 in the proximity of one of the nozzles for the emergence of the parting means,

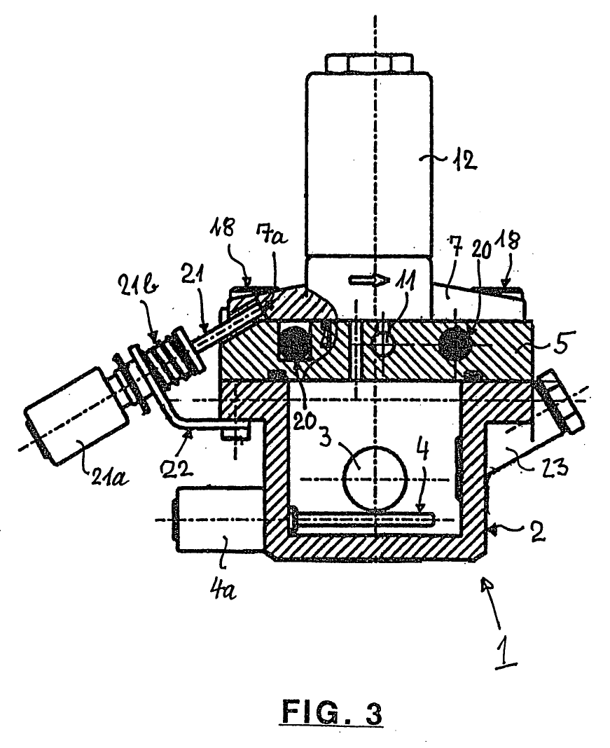

FIG. 3 a vertical cross section analogous to FIG. 2 in the proximity of the temperature sensors for the temperature of the liquid parting means and the nozzle fitting bar, and

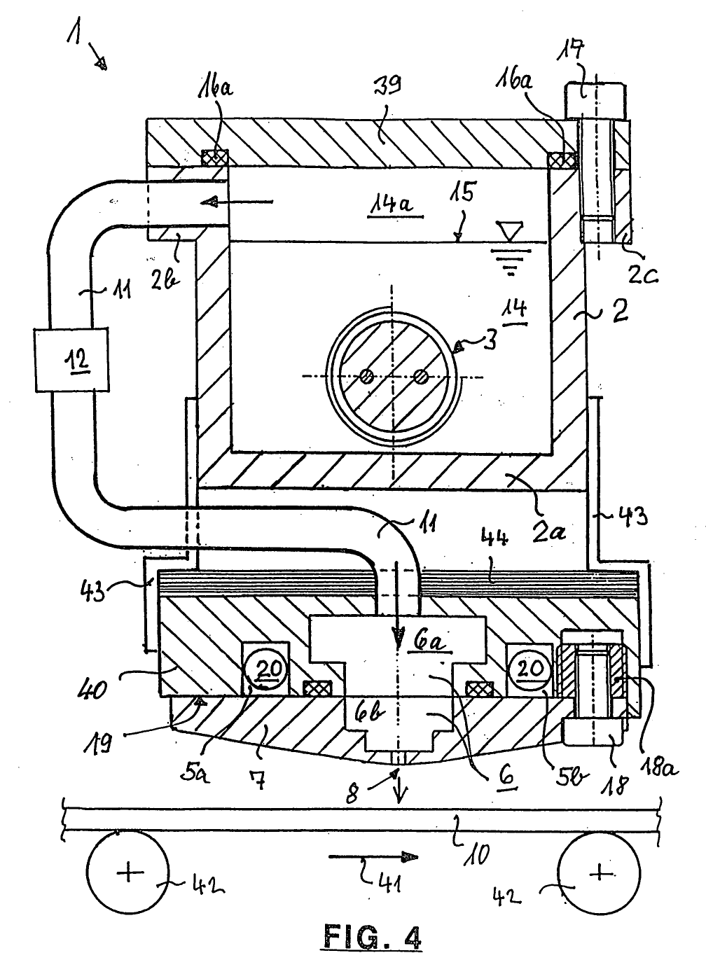

FIG. 4 a vertical cross section analogous to FIG. 2, however with the reverse direction of vapor emergence, namely downwardly.

FIG. 1 depicts a vaporizer I for the parting means, in the following referred to as oil. The vaporizer I is disposed in a (not shown) vacuum chamber and includes a lower, approximately cuboidal, chamber 2 for a supply of the oil to be vaporized. In the proximity of the bottom 2a is located an electric heating body 3 continuous in the longitudinal direction, which is tightly inserted at one end by means of a threaded connection 3a with a cable 3b. In the oil itself is also located a temperature sensor 4 for the acquisition of the oil temperature, which is adjusted for example to approximately 110° C. The other end of the vaporizer 1 can be implemented analogously with the exception of the threaded connection 3a.

The value of 110 degrees applies to conventional parting means, for example such from the group of polyfluoropolyethers, which are also employed as vacuum pump oils, for example under the designation “Fomblin”. These are high-molecular oils and inert, even against strongly corrosive media, as well as thermally stable and noncombustible (RÖMPP Chemie Lexikon, 1995, Georg-Thieme Verlag, Stuttgart and New York, pages 1421 and 3276, keywords “Fomblin” and “perfluoropolyether”). Thus, mixing them into the pump oils of the requisite vacuum pumps also does not present any problems.

The parting effect with respect to metallic coating substances on substrates, for example on synthetic films and paper webs, for example in the production of capacitors with an aluminum coating, is due to the precise layer thickness of the oil: the oil film on the substrate is heated by the condensing metal vapor, the oil vaporizes and, due to the particle stream of the vaporizing molecules of the oil, prevents an accumulation of the metal. If the quantity of the oil applied is too low, the parting effect is too low and a thin metal layer is applied on the strips of the substrate which are to be kept free of metal, since the oil supply on the substrate is consumed before the metal deposition is completed. If too much oil is applied, an oil layer remains on the substrate, which becomes distributed between two layers during the winding-up of the bands, such that the oil is smeared over larger areas of the partially metallized band. The precise and constant dosing of the parting means is consequently absolutely dictated, yet is difficult to attain.

Located above the chamber 2 and sealed is disposed an intermediate cover 5 and therein and above it an upper channel-form chamber 6, which extends parallel to the lower chamber 2 and serves as a distributor channel for vaporous oil. Above the chamber 6—again sealed—is disposed a nozzle fitting bar 7, which has a number of nozzles 8 placed in the longitudinal direction and according to a specified distribution pattern. Chamber 6 is comprised of two linear recesses 6a and 6b, which are implemented in the intermediate cover 5 and in the nozzle fitting bar 7 and communicate with one another (see FIG. 2).

Above the nozzle fitting bar 7 and parallel to it is disposed at a short distance a deflector roller 9 over which the band 10 to be coated, a synthetic film or a paper strip, is rewound from a supply roll onto a finishing roll, neither of which is depicted. The perpendicular arrows indicate the direction of advance.

The lower chamber 2 is connected with the upper chamber 6 via at least one channel 11, which is closed toward the outside by a threaded plug 11a, and the transition cross section, and therewith the vapor quantity per unit time, can be affected by an electrically controlled proportional valve 12 with a valve body 12a, which extends into the channel 11. Such voltage-controlled proportional valves 12 are commercially available for example from the firm Buirkert/Germany.

Since, relative to the sum of the cross sections of all nozzles 8, channel 6 has a relatively large cross section, the vapor quantity emerging from the individual nozzles 8 is in each instance of equal size. The vapor jets generate on the moving band 10 strip-form equidistant parting means or oil tracings 13 of equal width, whose purpose has already been explained. The nozzle fitting bar 7 is kept at a constant temperature of for example 120° C., such that on it, and thus not in the nozzles 8 themselves, condensation of the oil takes place which could change the cross sections.

Utilizing the same reference numbers as previously, FIG. 2 depicts the cuboidal chamber 2 with lateral flanges 2b and 2c and a supply of the oil 14 to be vaporized, which extends up to the liquid level 15. The intermediate cover 5 is congruently connected through bolts 17 with flanges 2b and 2c of chamber 2 with sealing elements 16 being interspaced. Of the bolts 17 only one is shown. Again interspacing sealing elements 16a, onto the intermediate cover 5 the nozzle fitting bar 7 is screwed by means of bolts 18 and a thermally insulated threaded sleeve 18a. Of each of these only one is shown. It is evident that the upper chamber 6 is formed at least substantially by countersinking in the intermediate cover 5 and in the nozzle fitting bar 7.

Beneath a parting line 19 between the intermediate cover 5 and the nozzle fitting bar 7 in the intermediate cover 5 are located grooves 5a and 5b for heating bodies 20, which essentially have the function to bring the nozzle fitting bar 7 to the required temperature and to maintain it at that temperature.

Again applying the same reference numbers as previously, FIG. 3 shows a section corresponding to practice analogous to FIG. 2 through the region in which a temperature sensor 21 is disposed for acquiring the temperature of the nozzle fitting bar 7. This temperature sensor 21 is fastened with its connection housing 21a on an angle bracket 22 and pressed by means of a compression spring 21b against an end face 7a of a bore in nozzle fitting bar 7. Further shown is the temperature sensor 4 for the oil and its connection housing 4a. By 23 is denoted a closable connection pipe fitting for replenishing the oil.

Considering an overall view of FIGS. 1, 2 and 3, the following feasibilities for the adjustment, control and/or regulation of the critical parameters of the vaporizer result: FIG. 1 depicts highly schematically a control system 24. This system receives initially via the temperature sensor 4 a measurement value for the temperature of the oil, whereby the heating body 3 can be adjusted to constant temperature values by means of a power setter 3c in a cable 3b across a line 25. The temperature sensor 21, here indicated only schematically, for the nozzle fitting bar 7 transfers its measurement value also to the control system 24, whereby the power of the heating bodies 20 according to FIG. 2 is adjusted across a line 26, and specifically also to constant temperature.

Especially important is the driving of the proportional valve 12 across line 27. For this purpose the deflector roller is provided with a rotational number transmitter 28, here only depicted highly schematically. This transmitter can be an optic sensor for acquiring the strip pattern on the deflector roller 9, or a magnetic sensor for rotating magnets, or'simply a revolution counter on the shaft, not shown here, of the deflector roller 9. Since the quantity of oil per unit time and nozzle should essentially be proportional to the band rate, hereby an ideal capability is given for optimizing the vapor streams and the oil layer thickness. During the stand-down of the deflector roller 9 the proportional valve 12 thereby assumes its closed position. For the same purpose and during an operational breakdown it is also feasible to provide an EMERGENCY SHUTDOWN switch integrated into the control system 24.

An additional optical or visual check of the layer thickness of the oil can take place in an observation field 29, through which pass the oil tracings 13. This field can be scanned for example by a video camera, or the optical reflections between light sources and photo sensors can be utilized via a line 30 for the manual control or automated regulation.

All of these measures can be applied either individually or in any desired combination. However, it is essential, that the temperatures of the oil and of the nozzle fitting bar 7 during operating either after the adjustment or by regulation for maintaining the tracking stability of the oil tracings 13 are kept constant and that the vapor streams from the nozzles 8 are interrupted in the shortest possible time in the event of a stand-down of the installation.

The control system 24 usefully includes an input keyboard 31 for setting commands and/or nominal values and an LCD display and/or a display screen 32 for visual observations.

Indicated is further—at a highly reduced scale—a metal vaporizer 33 comprised of a graphite boat 34 heated by current passage, in which is disposed a melt 35, for example of aluminum. This metal vaporizer 33 extends at least over the entire width of band 10. Associated with it is a measuring and regulation configuration 36, which receives its control signals, for example for the heating power, from control system 34] across a line 37. It is known that the metal quantity vaporized per unit time is at least substantially proportional to the heating power or the temperature. A report back of the temperature and/or the heating power takes place across a line 38 to control system 34. This allows the optimum tuning to one another by the control system 34 of the oil and metal quantities vaporized per unit time, because the oil and metal quantities, again, are proportionally related.

FIG. 4 depicts a vertical cross section analogous to FIG. 2, however with a reversed vapor emergence direction, namely downwardly. The same reference numbers are largely used, especially since the subject matter of FIG. 4 is largely comprised of the same structural components as that according to FIGS. 1 to 3.

In this case the first chamber 2 is the upper chamber and is closed with a first closure cover 39. The vapor space 14a above the parting means 14 (oil) is here also connected with a channel 11, which in this case is implemented as a bent-over tube line and in which is disposed the already described proportional valve 12. The second chamber 6 is in this case disposed beneath the first chamber 2 and “turned on its head”. Intermediate cover 5 according to FIGS. 1 to 3 is here implemented as closure cover 40. Channel 11 terminates through the second closure cover 40 in the second chamber 6, which, again, is comprised of two recesses 6a and 6b communicating with one another. The at least one nozzle 8 is directed with its vapor emergence direction downwardly onto a substrate 10, which is resistant against bending and which can be a plate or sheet of glass, for example for later use as an LCD pane. The transport path 41, which can be between-interlocks or magazines, is specified through several transport rollers 42.

The second chamber 6 is connected with the first chamber 2 through collars 43 and chambers 2 and 6 form a structural unit with parallel chambers 2 and 6. Since, compared to the first chamber 2, the second chamber 6 has conventionally a higher operating temperature, a thermal insulation layer 44 is advisable.

It is understood that, depending on the transport paths of the substrates, the spatial position of the parting means vaporizer 1 can be chosen differently, as long as the functional capability of the first chamber 2, the vaporizer chamber, is retained. Not only are oblique positions possible, but the chamber 6 with the nozzle fitting bar 7 can also be disposed laterally next to chamber 2, in order to coat for example vertically running bands. The subject matter of the invention forms a quasi modular system which can be rearranged in nearly any desired manner, as is evident in particular when comparing FIGS. 2 and 4.

### List of Reference Symbols

1 Vaporizer
2 First chamber.
2a Bottom
2b Flange
2c Flange
3 Heating body
3a Threaded connection
3b Cable
3c Power setter
4 Temperature sensor
4a Connection housing
5 Intermediate cover
5a Groove
5b Groove
6 Second chamber
6a Recess
6b Recess
7 Nozzle fitting bar
7a End face.
8 Nozzles
9 Deflector roller
10 Substrate
11 Channel
11a Threaded plug
12 Proportional valve
12a Valve body
13 Oil tracings
14 Oil (parting means)
14a Vapor space
15 Liquid level
16 Sealing elements
16a Sealing elements
17 Bolts
18 Bolts
18a Threaded sleeve
19 Parting line
20 Heating body
21 Temperature sensor
21a Connection housing
21b Compression spring
22 Angle bracket
23 Replenishment connection pipe fitting
24 Control system
25 Line
26 Line
27 Line
28 Rotational number transmitter
29 Observation field
30 Line
31 Input keyboard
32 Display screen
33 Metal vaporizer
34 Graphite boat
35 Melt
36 Measurement and regulation configuration
37 Line
38 Line
39 First closure cover
40 Second closure cover
41 Transport path
42 Transport rollers
43 Collars
44 Thermal insulation layer

1-27. (canceled)

28. A method comprising locally applying with a device for the localized application of a parting means preventing coating by means of a heatable vaporizer onto moving substrates in a vacuum chamber, which comprises at least one metal vaporizer, the parting means vaporizer comprising a first chamber with at least one heating body for the vaporization of the parting means as well as a second chamber extending parallel to the first chamber and connected with it, and comprising at least one nozzle directed onto the particular substrate, and with at least one setting valve for blocking the parting means supply, wherein
a) the at least one setting valve is a proportional valve, which is disposed between the first chamber and the second chamber,
b) the setting valve is disposed in one channel of the parting means vaporizer, which channel connects the first chamber with the second chamber, and
c) the setting valve is implemented such that the vapor stream of parting means is specifically adjustable in terms of quantity as well as is also completely interruptible, wherein a parting means preventing coating by heating parting means in the first chamber to vaporize the parting means and transferring the vaporized parting means into the second chamber via the at least one setting valve, by
a) keeping a vaporizer temperature in the vaporizer constant as much as possible,
b) supplying the vapor from the first chamber via the at least one setting valve under control into the second chamber and in the second chamber initially parallel to the first chamber to the at least one nozzle, and
c) closing the setting valve keeping it closed in the event the substrate stands still or is absent.

29. The method as claimed in claim 28, wherein the liquid parting means contained in the first chamber is kept at constant temperature through at least one electric immersed heating body, and that at least the wall of the second chamber, and therewith the at least one nozzle, is also kept at constant temperature through at least one further electric heating body, which is chosen to be above the boiling temperature of the parting means.

30. The method as claimed in claim 29, wherein the first chamber is disposed beneath and the second chamber in a higher position, and the vaporous parting means is directed with a perpendicular direction component from below against a band-form substrate.

31. The method as claimed in claim 28, wherein the first chamber is disposed above and the second chamber in a lower position, and the vaporous parting means is directed with a perpendicular direction component from above against a plate-form substrate.

32. The method as claimed in claim 28, wherein the wall temperature of the second chamber is adjusted to a higher value than the parting means temperature in the first chamber.

33. The method as claimed in claim 28, wherein the heating power of the immersed heating body is adjusted as a function of the parting means temperature.

34. The method as claimed in claim 28, wherein the heating power of the immersed heating body for the at least one nozzle is adjusted as a function of the nozzle temperature.

35. The method as claimed in claim 28, wherein the vapor quantity streaming from the first chamber over into the second chamber per unit time is adjusted through the at least one proportional setting valve as a function of the parting means requirement for the at least one nozzle.

36. The method as claimed in claim 28, wherein the vapor quantity of parting means emerging from the at least one nozzle per unit time is adjusted as a function of the layer thickness and the width of an oil tracking as well as the transporting rate of the substrate.

37. The method as claimed in claim 28, wherein the layer thickness of an oil tracing is adjusted proportionally to the metal quantity vaporized by the metal vaporizer per unit time.

38. The method as claimed in claim 28, wherein the at least one oil tracing is passed through an observation field in which a visual check of an oil tracing is carried out.

39. The method as claimed in claim 28, wherein the operating parameters critical for the implementation of the distribution pattern and of the necessary thickness of an oil tracing are supplied to a control system, in which they are converted into setting variables for the control and/or regulation of the vaporizer for the parting means.

40. The method as claimed in claim 28, wherein the operating parameters critical for the implementation of the metal coating are also supplied to the control system in which they are converted into setting variables for the control and/or regulation of the metal vaporizer.

41. A method for the localized application of a parting means preventing coating with a vaporizer onto moving substrates in a vacuum chamber, comprising at least one metal vaporizer, the parting means vaporizing in a first chamber by heating and in vaporous form transferred via at least one setting valve into a second chamber provided with at least one nozzle directed onto the particular substrate, wherein
a) the vaporizer temperature is kept as much as possible constant,
b) the vapor from the first chamber is supplied via the at least one setting valve under control into the second chamber and in the latter initially parallel to the first chamber to the at least one nozzle and that
c) the setting valve is closed and kept closed in the event the substrate stands still or is absent.

42. The method as claimed in claim 41, wherein the liquid parting means contained in the first chamber is kept at constant temperature through at least one electric immersed heating body, and that at least the wall of the second chamber, and therewith the at least one nozzle, is also kept at constant temperature through at least one further electric heating body, which is chosen to be above the boiling temperature of the parting means.

43. The method as claimed in claim 42, wherein the first chamber is disposed beneath and the second chamber in a higher position, and the vaporous parting means is directed with a perpendicular direction component from below against a band-form substrate.

44. The method as claimed in claim 42, wherein the first chamber is disposed above and the second chamber in a lower position, and the vaporous parting means is directed with a perpendicular direction component from above against a plate-form substrate.

45. The method as claimed in claim 41, wherein the wall temperature of the second chamber is adjusted to a higher value than the parting means temperature in the first chamber.

46. The method as claimed in claim 41, wherein the heating power of the immersed heating body is adjusted as a function of the parting means temperature.

47. The method as claimed in claim 41, wherein the heating power of the immersed heating body for the at least one nozzle is adjusted as a function of the nozzle temperature.

48. The method as claimed in claim 41, wherein the vapor quantity streaming from the first chamber over into the second chamber per unit time is adjusted through the at least one proportional setting valve as a function of the parting means requirement for the at least one nozzle.

49. The method as claimed in claim 41, wherein the vapor quantity of parting means emerging from the at least one nozzle per unit time is adjusted as a function of the layer thickness and the width of an oil tracking as well as the transporting rate of the substrate.

50. The method as claimed in claim 41, wherein the layer thickness of an oil tracing is adjusted proportionally to the metal quantity vaporized by the metal vaporizer per unit time.

51. The method as claimed in claim 41, wherein the at least one oil tracing is passed through an observation field in which a visual check of an oil tracing is carried out.

52. The method as claimed in claim 41, wherein the operating parameters critical for the implementation of the distribution pattern and of the necessary thickness of an oil tracing are supplied to a control system, in which they are converted into setting variables for the control and/or regulation of the vaporizer for the parting means.

53. The method as claimed in claim 41, wherein the operating parameters critical for the implementation of the metal coating are also supplied to the control system in which they are converted into setting variables for the control and/or regulation of the metal vaporizer.
